(19) United States
(12) Patent Application Publication
(10) Pub. No.: US 2025/0293481 A1
(43) Pub. Date: Sep. 18, 2025

(54) EXTERNAL CAVITY LASER LEVERAGING THE VERNIER EFFECT

(71) Applicant: TOPTICA Photonics, Inc., Pittsford, NY (US)

(72) Inventor: Mateus CORATO ZANARELLA, Fairport, NY (US)

(73) Assignee: TOPTICA Photonics, Inc., Pittsford, NY (US)

(21) Appl. No.: 19/181,429

(22) Filed: Apr. 17, 2025

(51) Int. Cl. H01S 5/14

(52) U.S. Cl. CPC H01S 5/141

(57) ABSTRACT

The invention relates to an optical radiation source. It is an object of the invention to enable the generation of laser radiation with (ultra) narrow linewidth and to provide an optical radiation source which is robust and simple to control. The optical radiation source of the invention comprises: a laser source having a gain medium and an internal cavity configured to generate laser radiation at multiple frequencies separated by a first free spectral range, at least one external cavity in optical communication with the laser source, the external cavity having a plurality of resonance modes within the gain bandwidth of the laser source, wherein the resonance modes are separated by a second free spectral range which is different from the first free spectral range, wherein the external cavity is configured to act as a frequency-selective reflector to selectively reflect laser radiation generated by the laser source back into the gain medium, thereby causing the gain medium to lase predominantly at only one frequency, and wherein the optical radiation source is configured to couple a portion of the generated laser radiation out from the internal cavity and/or from the external cavity.

### FIELD OF THE INVENTION

The invention relates to an optical radiation source comprising a laser source having a gain medium within an internal cavity, in combination with at least one external cavity configured to act as a frequency-selective reflector to selectively reflect laser radiation generated by the laser source back into the gain medium, wherein the optical radiation source is configured to couple a portion of the generated laser radiation out from the internal cavity and/or from the external cavity.

### BACKGROUND OF THE INVENTION

The significance of widely tunable, narrow linewidth diode lasers is evident across a diverse range of applications, including fiber optic communications, optical computing, ranging and optical sensing, laser cooling, and atomic clocks. As these applications continue to advance, the conventional single-frequency monolithic semiconductor diode laser sources, specifically distributed feedback (DFB) lasers and distributed Bragg reflector (DBR) lasers, are approaching their operational limits. These sources typically exhibit linewidths in the range of hundreds of kHz or wider, with a coarse tuning range not exceeding single digit nanometer intervals. Furthermore, they are commercially available only for selected regions of the optical spectrum due to fabrication constraints. Narrower linewidths are commercially achievable by fiber-based lasers, but at the cost of limited tunability, bulkiness, and high cost.

Narrower linewidths and wider tuning than those achievable with monolithic diode lasers have been demonstrated with optical radiation sources utilizing gain media coupled to one or more external cavities that alter/control the light emission, with sub-kHz linewidths being reached. Such arrangements can make use of lasing—e.g., Fabry-Perot laser diodes (FPLDs)—or non-lasing—e.g., semiconductor optical amplifier (SOA), reflective semiconductor optical amplifier (RSOA), superluminescent diode (SLED)—gain media, with free-space or integrated external cavities. In free-space cavities, the light emitted by the gain medium is focused, diffracted, and reflected by elements such as lenses, gratings and mirrors that form suitable external cavities. In integrated cavities, monolithic, hybrid and/or heterogeneously integrated gain media are coupled to one or more external cavities in photonic integrated circuits (PICs) fabricated in a specialized low-loss material platform. If the gain medium does not lase by itself, the external cavity/cavities complete the laser cavity. If the gain medium does lase by itself, the external cavity/cavities typically alter the laser emission through frequency-selective reflections to cause self-injection locking, which collapses the light emission into one or multiple selected frequencies.

The use of waveguides and optical components in PICs as external cavities is beneficial for several reasons. The index contrast between the waveguide core and cladding, which is controlled by the material platform of choice, enables waveguides with controllable degrees of modal confinement to engineer mode field diameters and sharp bends of negligible radiation loss, resulting in small footprint. The waveguides and components are defined by lithography and etching, providing intrinsic optical alignment between parts and unparalleled robustness, unlike in free-space optical systems. The integration of passive (e.g., splitters, couplers) and active (e.g., phase shifters, modulators) optical components on the same chip enables functionalities beyond those available in non-integrated platforms. Furthermore, techniques have been developed that allow for wafer-scale monolithic or heterogeneous integration with semiconductor gain media.

It is acknowledged that hybrid and heterogeneous integrated lasers based on frequency selection with two or more microring resonators (MRRs) and non-lasing sources (e.g., SOA, RSOA, SLED) are known in the art (see, for example, Klaus-J. Boller et al. (2020), Photonics 7, 4. doi:10.3390/photonics7010004). It is known that the PIC provides an external cavity by a number of integrated loop mirrors and MRRs for spectrally selective feedback in optical communication with the gain media, serving to increase the photon lifetime of the formed laser cavity, thereby reducing the laser linewidth. The PIC comprises phase shifters (e.g., integrated electrical heaters) for tuning the laser radiation by changing the physical properties (e.g., refractive index) of the integrated optical components (e.g., waveguides, MRRs). One disadvantage of this approach is that, since the PIC is part of the main laser cavity, the resulting integrated laser is extremely sensitive to the coupling loss between the gain media and the PIC, the propagation/insertion losses of the integrated components, and optical reflections from components/interfaces, which can prevent lasing and/or cause instabilities. Furthermore, non-lasing gain media are typically commercially available only for selected portions of the optical spectrum and with limited optical power (few to low tens of milliwatts).

It is also acknowledged that the disclosure of US 2023/0288774 A1 describes an optical radiation source comprising a FPLD as a laser source and a waveguide optically coupled to the laser diode and configured to carry the light. A feedback section is designed to reflect the light back into the gain medium of the laser diode via the waveguide. The feedback section comprises a MRR that is optically coupled to the waveguide. The design incorporates tuning elements, which are configured to tune both the MRR and the waveguide. The MRR is of a small size so that its free spectral range (FSR) exceeds the gain bandwidth of the laser diode. In this manner, solely a single lasing mode of the FPLD is reflected by the MRR, thereby causing single-frequency self-injection locking. One disadvantage of this approach is that it is constrained to FPLDs with a sufficiently narrow gain bandwidth, limited by how small the MRR can be fabricated. Furthermore, the relatively small dimensions of the MRR result in a comparatively high loss and high thermorefractive noise (TRN), which in turn limit the achievable linewidth of the generated laser radiation. Other works have employed larger MRRs or bulky whispering gallery mode resonators to lower the losses and the TRN in order to achieve narrower linewidths (see, for example, A. Isichenko et al. (2023), arXiv:2307(dot)04947, https://doi(dot)org/10(dot)48550/arXiv(dot)2307(dot)04947), but at the expense of limited laser tunability, compromised long-term stability, propensity for mode-hopping, and/or lack of chip-scale integration.

In a research article published in Optics Letters (vol. 48, no. 22, pp. 5972-5975), Andrei N. Danilin and colleagues present a method for controlling multi-frequency self-injection locking in a multimode laser diode with a tunable free spectral range. In other words, they describe a way to adjust the frequency interval between two successive lines in the spectrum of the generated optical radiation. The setup comprises a RSOA in combination with a partially reflective mirror forming a laser cavity. In addition, a PIC is provided, comprising a MRR that is in optical communication with the laser cavity. The MRR functions as a frequency-selective reflector, directing laser radiation back into the gain medium of the laser cavity. This results in the gain medium simultaneously emitting light at multiple frequencies where the resonance modes of the MRR and the frequencies of the laser cavity are matched. The free spectral range of the laser diode can be varied by adjusting its length, thereby enabling the generation of laser radiation with a number of self-injection-locked narrow lines on demand. Disadvantages of this arrangement include difficult and limited tuning, poor long-term stability, and propensity for mode-hopping. This is primarily due to the large length of the laser cavity required to implement the control of its FSR, which creates lasing frequencies that are too closely spaced. Consequently, dimensional fluctuations as small as tens of nanometers change the number and position of the self-injection locked laser lines, causing mode-hopping and restricting tuning. The stability and repeatability are further limited by the difficulty in controlling and stabilizing the phase delay of the reflected light. All these disadvantages render such laser architecture impractical.

In another research article published in Journal of Lightwave Technology (vol. 36, no. 16, pp. 3269-3274), Y. Li and colleagues present a method leveraging the FSR difference between an FPLD and one MRR reflector of small radius to achieve single-frequency lasing. The FPLD receives a reflection that causes self-injection locking only where the resonance modes of the MRR match those of the FPLD, forming an optical Vernier effect due to their FSR difference. Disadvantages of their arrangement include a large limit for the laser's intrinsic linewidth as a result of the higher loss and TRN of the small ring, whose FSR spans multiple FSRs of the FPLD. Another disadvantage is the trade-off between the laser linewidth and output power, since they are determined predominantly by the MRR resonance's linewidth and extinction. A narrower laser linewidth results in smaller output power, which is undesirable. Against this background it is readily appreciated that there is a need for an improved optical radiation source.

### SUMMARY OF THE INVENTION

It is thus an object of the invention to enable the generation of essentially single-frequency laser radiation with (ultra) narrow linewidth and wide tunability, and to provide an optical radiation source which is robust, stable, scalable, and simple to control.

In accordance with the invention, an optical radiation source is disclosed, comprising:
a laser source having a gain medium and an internal cavity configured to generate laser radiation at multiple frequencies separated by a first free spectral range,
at least one external cavity in optical communication with the laser source, the external cavity having a plurality of resonance modes within the gain bandwidth of the laser source, wherein the resonance modes are separated by a second free spectral range which is different from the first free spectral range,
wherein the external cavity is configured to act as a frequency-selective reflector to selectively reflect laser radiation generated by the laser source back into the gain medium, thereby causing the gain medium to lase predominantly at a single frequency, and
wherein the optical radiation source is configured to couple a portion of the generated laser radiation out from the internal cavity and/or from the external cavity.

The disclosed optical radiation source made possible by this invention enables simultaneously (ultra) narrow linewidth (by allowing for large frequency-selective reflectors with low loss and low TRN), scalability of optical power and wavelength (by using a gain source that lases by itself, and by using a splitter independent of the external reflector or by collecting the output light directly from one end of the gain source), large coarse tunability (by allowing for gain media with wide bandwidth and by selecting the lasing frequency through the tuning of the external cavity and/or the gain medium), wide fine tunability (by frequency pulling through the tuning of the external cavity, with or without feed-forward control of the gain medium), robustness and long-term stability (by having the external cavity separate from the lasing cavity containing the gain medium), and simple control. As highlighted before, existing technologies compromise one or more of these properties to achieve others, while our invention enables realizing all of them simultaneously.

### BRIEF DESCRIPTION OF THE DRAWINGS

The enclosed drawings disclose preferred embodiments of the present invention. It should be understood, however, that the drawings are designed for the purpose of illustration only and not as a definition of the limits of the invention. In the drawings:

FIGS. 1A, 1B show schematics of example optical radiation sources in accordance with the present invention;

FIG. 2 shows diagrams illustrating the Vernier effect utilized in the design of the optical radiation source according to the present invention.

### DETAILED DESCRIPTION OF THE EMBODIMENTS

Disclosed herein are optical radiation sources.

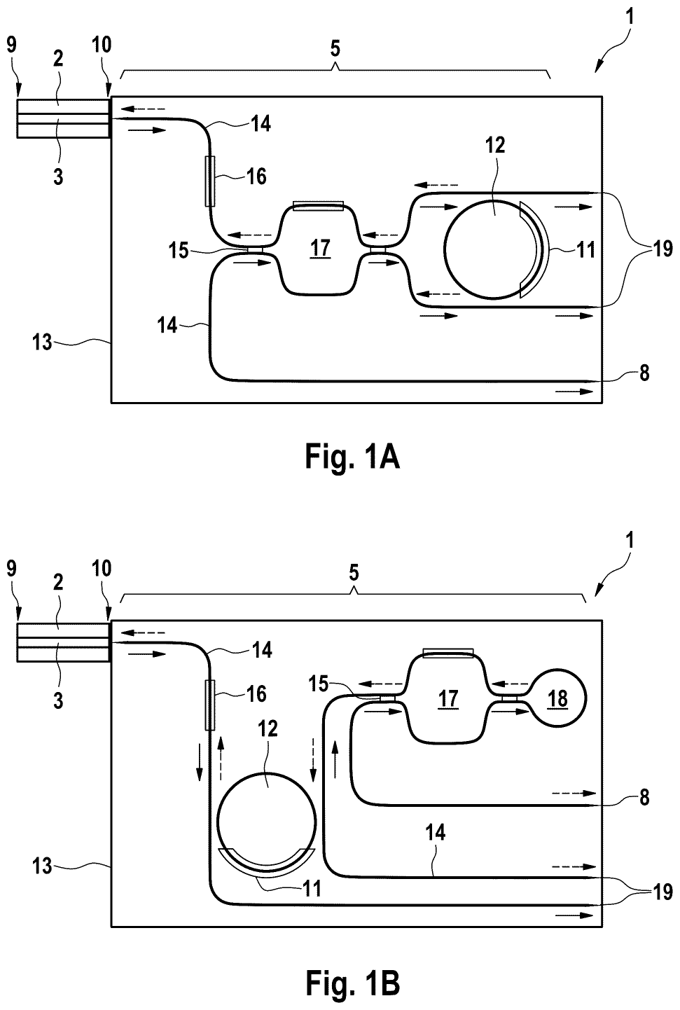

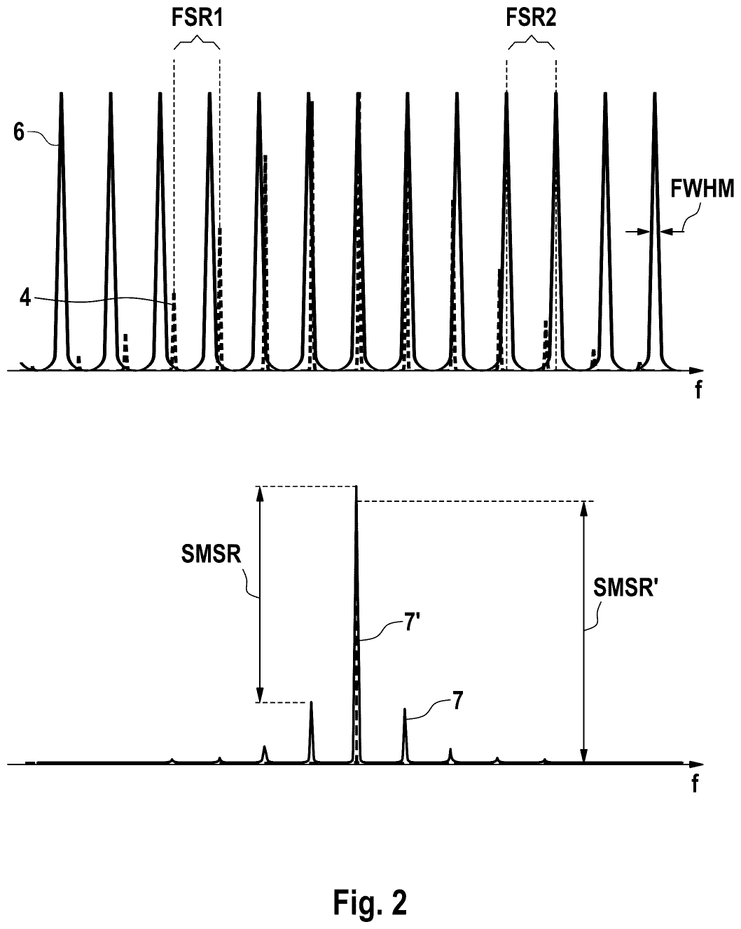

Example optical radiation sources 1 are schematically shown in FIGS. 1A, 1B. The respective optical radiation source comprises a laser source 2 having a gain medium 3 and an internal cavity configured to generate laser radiation at multiple frequencies separated by a first free spectral range FSR1. The multi-line spectrum of the laser radiation generated in the internal cavity of the laser source 2 in the absence of an external cavity is illustrated in the left diagram of FIG. 2 and is designated by reference number 4. The diagram shows the intensity of the respective frequency components varying as a function of frequency f in accordance with the gain bandwidth of the gain medium 3. At least one external cavity 5 is in optical communication with the laser source 2. The external cavity 5 has a plurality of resonance modes within the gain bandwidth of the laser source 2, wherein the resonance modes are separated by a second free spectral range FSR2 which is different from the first free spectral range FSR1. The resonance modes of the external cavity are shown in the left diagram of FIG. 2 as well, overlaid with the spectrum of laser source 2, designated by reference number 6. The external cavity 5 is configured to act as a frequency-selective reflector to selectively reflect laser radiation generated by the laser source 2 (which enters the external cavity 5 as indicated by solid arrows in FIGS. 1A, 1B) back into the gain medium 3 (as indicated by the dashed arrows in FIGS. 1A, 1B), thereby causing the gain medium 3 to lase (predominantly) at a single frequency determined by the peak wavelength of the reflection through self-injection locking. The overlap between the emission spectrum of the laser source 2 prior to self-injection locking (spectrum 4 in FIG. 2) and the reflection spectrum of the external cavity 5 (spectrum 6 in FIG. 2) result in an effective reflection spectrum with a single predominant peak (spectrum 7 in FIG. 2) due to the Vernier effect. If the side-mode suppression ratio of the reflection (SMSR) is large enough, which is determined by the Vernier effect design through FSR1 and FSR2, the self-injection locking causes the laser source 2 to emit (predominantly) at a single frequency 7′ aligned with the peak of the reflection with an increased side-mode suppression ratio (SMSR′) (overlaid with the reflection spectrum 7). The optical radiation source 1 is further configured to couple a portion of the generated laser radiation out from the external cavity 5 at outputs 8, 19 and/or from the laser cavity at facet 9. The laser source 2 can also be optically coupled to the external cavity from either one or both of the facets 9 and 10.

The laser source 2 is preferably a semiconductor-based laser. The gain medium 3 is typically a stack of semiconductor layers (active region) in a chip with a diode structure made from materials like indium gallium arsenide phosphide (InGaAsP), aluminum gallium arsenide (AlGaAs), indium phosphide (InP), aluminium gallium indium phosphide (AlGaInP), indium gallium nitride (InGaN), or others. The gain bandwidth refers to the range of wavelengths over which the gain medium can amplify light. It is determined by the material properties and the structure of the gain medium. The gain bandwidth for typical semiconductor materials can range from a few nanometers to tens of nanometers, depending on the design.

The internal cavity of the laser source is usually formed by two parallel reflective facets 9, 10 on either side of the gain medium 3, acting as mirrors. This may form a Fabry-Perot resonator, which determines the allowed frequencies of the laser source 2. The first free spectral range FSR1 is the frequency spacing between adjacent modes of the internal cavity (i.e. in absence of the external cavity). The first free spectral range FSR1 is thus the distance between each two of the multiple frequencies that are adjacent in the spectrum 4 of the laser radiation generated by the laser source 2. In other words, the first free spectral range FSR1 defines the frequency separation between the modes supported by the internal cavity, and the gain medium 3 can only lase at the frequencies of these modes within the gain bandwidth of the laser source 2. As the laser source 2 is able to generate laser radiation at multiple frequencies, the gain bandwidth must be broad enough to support multiple modes of the internal cavity.

In particular, FPLDs naturally exhibit multi-mode behavior because their gain bandwidth often spans a multiple of the first free spectral range FSR1 of the internal cavity. This allows the gain medium 3 to lase at several frequencies simultaneously, each separated by the first spectral range FSR1.

The external cavity 5 refers to an optical setup that includes additional components outside the semiconductor chip of the laser source 2 to modify and enhance the properties and capabilities of the optical radiation source 1, such as frequency tuning, linewidth narrowing, and mode structure control. While, as mentioned above, the internal cavity is typically formed by the reflective facets 9, 10 of the semiconductor chip of the laser source 2 itself, the external cavity 5 extends this configuration by introducing additional optical components, such as reflectors, gratings, resonant cavities, outside the laser source 2. This creates a longer resonator, where the interaction between the internal and external cavities determines the overall laser characteristics. By increasing the effective cavity length, the external cavity 5 significantly reduces the linewidth of the laser emission. The effective cavity length can be increased as desired to achieve a very narrow-line laser emission.

Self-injection locking occurs as the output of the laser source 2 is reflected back into the gain medium 3 through the external cavity 5 in a frequency-selective fashion. This feedback collapses the power emitted by the laser onto a specific frequency 7′ determined by the internal and external cavities 2, 5, leading to a highly stable and narrow-line operation.

The external cavity 5 has a plurality of resonance modes 6 separated by a second free spectral range FSR2 (see left diagram of FIG. 2). The second free spectral range FSR2 is the frequency spacing between adjacent resonance modes 6 of the external cavity 5. The presence of multiple resonance modes 6 means that the external cavity 5 can provide feedback at several distinct frequencies to the laser source 2. If the resonance modes 6 of the external cavity 5 coincide with or are close to or identical with the internal cavity modes 4, they reflect a portion of the light at those frequencies back to the gain medium 3, causing mode collapse and linewidth narrowing through self-injection locking.

The optical radiation source 1 is configured to couple a portion of the generated laser radiation out from the internal cavity and/or from the external cavity 5. In a possible embodiment, one or both of facets 9, 10 of the gain medium 3 may be configured to be partially reflective (typically around 30-70% reflectivity, but can range from as low as below 1% to as high as above 90%). The reduced reflectivity facet allows a portion of the generated laser light to be coupled out directly from the internal cavity. In another possible configuration, the external cavity components themselves can be used to couple out the laser light. Furthermore, one or more splitters, such as Y-junctions, multi-mode interferometers (MMIs), tunable splitters or directional couplers, may be used to split the laser radiation circulating between the internal and external cavities and to divert a portion of this laser radiation out of the system (at outputs 8, 19) while allowing the remaining laser radiation to be fed back into the gain medium 3. These splitters enable independent control of the external cavity's output power (determined mostly by the splitter's splitting ratio) and the laser linewidth (determined mostly by the external reflector's linewidth).

In embodiments of the invention, the laser source 2 and the external cavity 5 are combined to leverage the Vernier effect resulting from the different first and second free spectral ranges FSR1, FSR2 to reflect the laser radiation selectively back into the gain medium 3 at one main/predominant frequency of laser radiation coinciding with the resonant modes of the external cavity 5 with a significant side mode suppression ratio (SMSR), resulting in the power collapse to only one (predominant) frequency 7′ and in the suppression of other frequencies of the laser radiation (increased SMSR′), as can be seen in the right diagram of FIG. 2. In general, the Vernier effect occurs when two or more resonators with different free spectral ranges are combined and satisfy the following relationship:

$${FSR}_{v} = {M}_{1} X {FSR}_{1} = {M}_{2} X {FSR}_{2} = ⋯ = {M}_{N} X {FSR}_{N} \qquad ( 1 )$$

where FSRᵥ is the effective FSR of the Vernier effect, FSRᵢ is the FSR of the i-th resonator, Mᵢ (i=1, 2, . . . , N) are co-prime numbers, and N is the total number of resonators. The laser source 2 comprises a resonator that has intracavity gain. When the resonances of the (two or more) resonators align, constructive interference occurs, and the combined system enhances only certain frequencies. Selective feedback is provided in this way. The Vernier effect allows only the frequencies of the laser source 2 that match the overlapping resonances of both the internal and external cavities to be reflected back into the gain medium 3. Other frequencies, which do not match, are suppressed due to insufficient feedback or destructive interference. One major advantage of this configuration is the ability to achieve stable single-frequency lasing with arbitrarily large external cavities. By carefully designing the optical length of the external cavity 5, the Vernier effect can be used to ensure that only one (predominant) resonance mode aligns between the internal and external cavities, suppressing all other modes. This is particularly beneficial in applications requiring narrow-linewidth laser radiation. Furthermore, the Vernier effect provides a natural mode suppression mechanism by ensuring that only frequencies coinciding with both cavity resonances receive sufficient feedback to lase. This increases mode stability and improves overall laser performance. The Vernier effect ensures that the majority of the energy of the generated laser radiation is concentrated in the single (predominant) selected mode, improving output power efficiency for the desired lasing frequency.

In possible embodiments, corresponding to the particular case |M₂−M₁|=1 in equation (1), the first and second free spectral ranges FSR1, FSR2 differ only slightly, namely by a value comparable to or greater than the full width at half maximum (FWHM) of the external cavity resonances, as illustrated in the left diagram of FIG. 2. In possible embodiments, the ratio of the first and second free spectral ranges can be in the range of 0.9-1.1, meaning 0.9<FSR1/FSR2<1.1. In this case, equation (1) can be rewritten as FSRᵥ=FSR₁×FSR₂/|FSR₁−FSR₂|. The small difference between the free spectral ranges FSR1, FSR2 of the two cavities means that the overlap of resonances is more selective, i.e. the spectral distance FSRᵥ between the occurrence of overlaps of resonances is larger. By making both FSRs very close to each other, a large resonator can be used to result in a very narrow laser linewidth. At the same time, the FSR difference must be designed to be large enough compared to the FWHM of the external cavity modes to yield high enough SMSR for the self-injection locking, since a smaller difference decreases the SMSR. The gain medium 3 in the internal cavity will only lase at the frequencies where both cavity resonances coincide, which results in narrower laser linewidths. The slight difference in free spectral range can thus be exploited to ensure that only one mode is preferentially selected for lasing as it can be achieved that only one mode of the internal cavity within the gain bandwidth coincides with a resonance mode of the external cavity 5 while all other modes are strongly suppressed. In other words, the effective FSR provided by the Vernier effect (FSRᵥ) should be comparable to or larger than the gain bandwidth of the laser source in this embodiment. This results in a (predominantly) single-mode, single-frequency narrow-linewidth operation. A further advantage is that the likelihood of mode hopping is reduced, leading to a more stable operation of the optical radiation source. The choice of the difference |FSR₁−FSR₂| compared to the FWHM, or equivalently the condition dictated by equation (1) in the general case of the Vernier effect, must be determined for the specific design of the optical radiation source 1 considering the properties of its parts and the desired performance metrics, including the free spectral range (FSR1) of the laser source 2, the FWHM of the reflection from the external cavity 5, the reflectivities of the laser facets 9 and 10, the target TRN limit, among others. The skilled person must design the system parameters in such a way that the described and appropriate Vernier effect is achieved.

It is worth noting that the second free spectral range FSR2 can be the result of multiple resonators and structures in the external cavity, not limited to a single resonator or structure. Also, the first and/or second free spectral ranges FSR1, FSR2 might deviate from the nominal FSR1/FSR2 values across the range of optical frequencies if the dispersion of the gain medium 3 and/or external cavity 5 is non-negligible. This, however, does not fundamentally change the design intent of the Vernier effect, and can rather be exploited to increase the reflection SMSR even further.

In embodiments of the invention, the laser source 2 may be one of: a FPLD (preferable, as in FIG. 1), a RSOA combined with a reflector to form an internal cavity having a plurality of resonance modes separated by the first free spectral range FSR1, or a SOA or SLED combined with two reflectors to form an internal cavity having a plurality of resonance modes separated by the first free spectral range FSR1. This demonstrates various ways of realizing the invention with different types of semiconductor-based laser sources. A FPLD uses the reflectivity of its facets 9, 10 to form the internal resonator. The diode supports multiple longitudinal modes due to the resonant feedback between the two partially reflective facets 9, 10. FPLDs are relatively simple to manufacture, widely available for a wide range of optical powers and wavelengths, and cost-effective compared to more complex laser designs. FPLDs can efficiently convert electrical energy into optical energy and they provide high output power. A RSOA is a component that amplifies light when injected into its active region and has a highly reflective surface on one end, thereby creating a single-ended device. The RSOA does not oscillate like a laser on its own but amplifies incoming light. When combined with an additional reflector (such as a mirror, grating, or a reflective resonator, not depicted), the reflector forms an internal cavity with the RSOA. This cavity supports multiple longitudinal modes separated by the first free spectral range FSR1. The RSOA typically has a wide gain bandwidth, which allows it to amplify a broad range of frequencies. This makes it suitable for widely tunable laser designs. SOAs and SLEDs are similar to RSOAs but do not have a built-in reflective facet. They are two-ended devices designed to amplify light that passes through them. When combined with two reflectors (which can be mirrors, gratings, reflective resonators, not depicted), they form a Fabry-Perot-like internal cavity. The reflectors define the cavity length and the separation between resonance modes, which determine the first free spectral range FSR1. Using external reflectors with RSOAs, SOAs, or SLEDs allows for increased flexibility in tuning the properties of the laser source. The reflectors (and their distance) can be adjusted to vary the cavity length, modifying the lasing wavelength or free spectral range.

In possible embodiments, the external cavity 5 is tunable, allowing selective tuning of the resonance modes of the external cavity 5 to control the lasing wavelength. Tuning the external cavity 5 allows matching the resonance modes of the external and internal cavities to select the desired frequencies. The external cavity 5 may be tunable by mechanically, electrically or thermally adjusting the physical properties (e.g., refractive index), position, dimension or orientation of one or more elements of the external cavity. The resonance modes of the external cavity 5 are determined by the cavity length, the refractive index of the medium inside the cavity, and the arrangement of optical elements like mirrors, splitters, resonators, or gratings. By adjusting the parameters of the external cavity, the second free spectral range FSR2 and/or the position of the resonances can be modified. This allows for the selective tuning of the optical radiation source's emission frequencies. The first free spectral range FSR1 and/or the position of the modes emitted by the laser source 2 can also be adjusted by changing the physical properties of the laser source, such as its current and temperature. The tunable external cavity 5 allows control over the feedback provided to the internal cavity of the laser source 2. By tuning the external cavity 5, the feedback can be adjusted to self-injection lock a specific single mode within the gain bandwidth. The external cavity 5 can be continuously tuned across a wide range of wavelengths by adjusting its elements incrementally. This fine-tuning capability is especially important in applications requiring precise control of the output frequency of the radiation source. Combined with a fine adjustment of the laser source 2, lasing at any arbitrary wavelength within its gain bandwidth can be achieved.

Mechanical tuning, electrical tuning (via piezoelectric actuators or MEMS), or thermal tuning can provide sub-GHz resolution in optical frequency control, enabling very precise and stable operation. Mechanical tuning involves physically changing the position or orientation of one or more components in the external cavity 5. For instance, a mirror or diffraction grating can be moved using mechanical actuators or piezoelectric devices to adjust properties such as the cavity length or the angle of incidence. This type of tuning is often used for broad-range wavelength adjustment, allowing the external cavity 5 to shift its resonant modes over a wide range. Mechanical tuning is often highly precise, with high stability over time. Electrical tuning is achieved by using elements like micro-electromechanical systems (MEMS) or piezoelectric actuators. Electrical tuning can also be performed by exploiting the electro-optic effect (Pockels Effect) to vary the effective refractive index of the external cavity. Thermal tuning involves changing the temperature of the external cavity or its elements (e.g., a section 11 of a ring resonator 12 in FIG. 1), which then alters the refractive index of the medium in the cavity. This method is highly effective for fine-tuning the wavelength, as small temperature changes can lead to slight shifts in the frequencies of the cavity's resonance modes. This method is commonly used for long-term tuning stability or applications that require high precision in wavelength adjustment. The tunable external cavity 5 enables the optical radiation source to cover a broad range of wavelengths.

In still other embodiments, the optical radiation source comprises an active or passive stabilization mechanism to maintain the alignment and/or the stability of the external cavity 5 and/or laser source 2, and/or the coupling of the laser source 2 to the external cavity 5. This stabilization mechanism is essential for ensuring consistent performance, especially in precision applications where even small misalignments or drifts, temperature changes, or changes in any physical parameter of the system can have a significantly adverse effect. Active stabilization refers to means that use feedback control loops and real-time adjustments to actively correct any drifts or misalignments in the external cavity 5/laser source 2, or the coupling between the laser source 2 and the external cavity 5, or changes in any physical property of the external cavity 5/laser source 2. These means typically include sensors (such as thermistors, position sensors, photodiodes, optical feedback monitors, or interferometers, not depicted) that detect changes in the temperature, position, orientation, optical power, current, or stability of the external cavity 5 components and laser source 2. The sensors feed this information to a control system (such as a microcontroller), which then makes real-time adjustments using actuators (e.g., piezoelectric elements, heating elements or MEMS devices) to correct the alignment, temperature, or cavities properties. Passive stabilization relies on inherent design features that reduce sensitivity to environmental changes such as temperature fluctuations, mechanical vibrations, or aging effects. This could include using thermally stable materials for the external cavity components, which have very low coefficients of thermal expansion. Passive stabilization means can include mechanical dampers or vibration-isolation mounts that reduce the effect of external mechanical vibrations on the cavity alignment, or even the gluing or fusion of the laser source to the external cavity. Additionally, PICs (as in the embodiments shown in FIGS. 1A, 1B) inherently increase the stability of the system since all its components are intrinsically aligned as defined by lithography and etching during its microfabrication processes. The external cavity components remain always optically aligned and connected regardless of vibrations or temperature changes in the system.

In possible embodiments, as shown in FIGS. 1A, 1B, the external cavity 5 is integrated into a PIC 13. This is the preferable implementation of the external cavity, as PICs present properties that cannot or can hardly be achieved with other external cavities. For example, since the size of a PIC is comparable to the size of a typical FPLD, and the length/shape of PIC components are defined with sub-micrometer precision through semiconductor manufacturing processes, both enable the efficient, precise, and highly controllable design of the Vernier effect between the internal and external cavities, which is fundamental for the performance of the optical radiation source 1. The laser source 2 may be optically coupled to or integrated into the PIC 13. The PIC 13 consists of waveguides 14 fabricated on a chip, allowing the laser radiation to be routed between different components. These waveguides 14 confine and guide the laser radiation through total internal reflection, like in optical fibers but in a more compact design. The waveguide paths can be shaped to form complex optical circuits with a variety of integrated photonic elements. The waveguides 14 are typically made of higher-index materials (such as silicon, silicon nitride, lithium niobate, aluminum nitride, aluminum oxide, etc.) on a lower-index substrate (such as silicon dioxide, sapphire, etc.) and covered with a lower-index cladding (such as silicon dioxide, etc.), ensuring efficient confinement of the laser radiation. Further components that can be integrated are directional couplers 15 that split or combine the light in a controllable fashion between different waveguides, allowing complex routing and control of laser radiation paths within the circuit. Gratings or filters (not depicted) can be integrated into the circuit to act as wavelength filters or dispersive elements, critical for functions such as wavelength selection or dispersion compensation. Integrating the external cavity 5 into the PIC 13 results in a highly compact design. All optical components are fabricated on a single chip, greatly reducing the size of the system and improving its stability compared to traditional free-space or fiber-coupled laser setups. This compactness also makes the system more robust to environmental influences (such as vibrations, temperature fluctuations, and mechanical stress), since all the components are defined by lithography/etching and are intrinsically optically aligned through waveguide connections. PICs are fabricated using semiconductor manufacturing techniques, which allow for scalability and the possibility of mass production. This greatly reduces the cost per device, making it feasible to manufacture large numbers of compact, high-performance optical radiation sources 1 with integrated external cavities 5. With the external cavity 5 integrated into the PIC 13, integrated tunable elements, such as the ring resonator 12 or the phase shifter 16 or the tunable splitter 17, can be used to adjust the resonance condition of the cavity, allowing for wavelength tuning and power tuning as described above. The integration of electrically tunable elements 16, 11, 17, allows for rapid and precise control of the lasing wavelength and laser output power. The waveguides 14 in the PIC 13 are designed for minimal optical loss, ensuring that the laser radiation is efficiently guided between components with minimal scattering or absorption. This results in a further reduction of the linewidth of the generated laser radiation, and a high coupling efficiency between the laser source 2 and the external cavity 5, thereby improving the overall performance of the optical radiation source 1.

In possible embodiments, the external cavity 5 comprises one or more ring resonators, namely MRR 12 in FIGS. 1A, 1B. An MRR functions by allowing the laser radiation to circulate in a closed loop. Only specific wavelengths that satisfy the resonance condition of the ring will constructively interfere and be enhanced. The resonance condition depends on the circumference of the ring and the effective refractive index of the waveguide material used. The ring resonator 12 acts as a frequency-selective element in the external cavity 5, allowing only specific resonance modes (determined by the ring's dimensions and refractive index) to exist in the cavity 5. Other frequencies are filtered out or attenuated, ensuring that only the desired frequencies are fed back to the laser gain medium 3. An advantage of using a ring resonator 12 in the external cavity 5 is its ability to provide precise wavelength selection. By adjusting the refractive index of the ring resonator (e.g., through thermal or electrical tuning), the resonance wavelengths can be finely tuned, allowing for high-resolution wavelength control. This allows for dynamic control of the frequency of the laser radiation, making it possible to adjust the output of the optical radiation 1 source in real-time. MRRs are especially advantageous due to their compact size. They can confine the laser radiation within a very small structure, making them ideal for integrated waveguide circuits. MRRs can achieve high Q-factors, meaning they can store the laser radiation for many cycles before it decays. A high Q-factor translates into sharp resonance peaks (narrow FWHM in FIG. 2), thus allowing for narrowband feedback into the gain medium 3 and, overall, for a narrow linewidth of the generated laser radiation.

A comparatively large MRR can be used in embodiments of the invention as the second free spectral range FSR2 can be comparatively small when leveraging the Vernier effect as explained above. As a result, a yet narrower linewidth of the generated laser radiation can be achieved, while retaining the highly selective optical feedback and the ease of tuning of the lasing frequency.

In possible embodiments, as in FIGS. 1A, 1B, the laser source 2 is optically coupled to the external cavity 5 via an integrated optical waveguide 14 and integrated adjustable phase shifter 16 of the PIC 13. The laser source 2 can be coupled to the external cavity via either or both of facets 9 and 10. The phase shifter 16 allows fine-tuned control over the phase of the laser radiation that is fed back into the gain medium 3. This configuration provides enhanced control over the lasing characteristics, such as wavelength stability, mode selection, and phase coherence. The electrical or thermal control of the phase shifter 16 ensures that the resonance conditions within the external cavity 5 are maintained, optimizing the feedback that the cavity 5 provides to the gain medium 3. The phase of the laser radiation fed back into the gain medium 3 determines how the external cavity 5 interacts with the modes of the internal cavity. If the feedback radiation is out of phase with the internal laser modes, destructive interference can occur, leading to mode competition or mode hopping. The phase shifter 16 ensures that the feedback laser radiation is phase-matched with the internal cavity modes, providing constructive interference and reinforcing the desired lasing mode. This leads to stable single-mode operation with reduced noise and a narrow linewidth.

In possible embodiments, the laser source 2 is optically coupled to the external cavity 5 via the integrated splitter 17 of the PIC 13 to split the laser radiation into a first portion coupled into the external cavity 5 and a second portion coupled out from the optical radiation source 1 via output 8. The integrated splitter 17, which can have a tunable (as in FIGS. 1A, 1B, via the phase shifter in one of the arms of a Mach-Zehnder interferometer) or fixed (not depicted) splitting ratio, splits the laser radiation between two (or more) waveguide paths. Its function is based on the principle of evanescent field coupling, where light propagating in one waveguide induces a portion of its energy to couple into an adjacent waveguide. The coupling ratio (i.e. the relative portions of the laser radiation split between the two waveguides) can be precisely designed. The integrated splitter 17 in the PIC 13 can be placed before (FIG. 1A) or after (FIG. 1B, which also includes a waveguide loop mirror 18) the resonant cavity elements (e.g., the MRR 12 in FIGS. 1A, 1B), allowing for splitting of the incoming laser light into a reflected portion that goes back to the laser gain medium 3, and transmitted portions that go to the external cavity outputs 8, 19. The design with the splitter 17 placed after the frequency-selective elements (FIG. 1B) provides a twice as long external cavity, thereby reducing the laser linewidth further. However, it provides lower output power at output 8 for the same amount of reflection back to the laser gain medium 3 when compared to placing the splitter 17 before the frequency-selective elements (FIG. 1A). This shows that the design versatility of the external cavity 5 allows it to be tailored to different applications while still providing the selective Vernier effect-based optical feedback that results in single-frequency, narrow-linewidth laser emission.

In other embodiments (not depicted) multiple laser sources with individual gain media (and internal cavities) can be coupled to one or multiple external cavities integrated in the same PIC, wherein the Vernier effect is leveraged for each gain medium.

1. An optical radiation source, comprising:
a laser source having a gain medium and an internal cavity configured to generate laser radiation at multiple frequencies separated by a first free spectral range,
at least one external cavity in optical communication with the laser source, the external cavity having a plurality of resonance modes within the gain bandwidth of the laser source, wherein the resonance modes are separated by a second free spectral range which is different from the first free spectral range,
wherein the external cavity is configured to act as a frequency-selective reflector to selectively reflect laser radiation generated by the laser source back into the gain medium, thereby causing the gain medium to lase predominantly at a single frequency, and
wherein the optical radiation source is configured to couple a portion of the generated laser radiation out from the internal cavity and/or from the external cavity.

2. The optical radiation source of claim 1, wherein the laser source and the external cavity are combined to leverage the Vernier effect resulting from the different first and second free spectral ranges to reflect the laser radiation selectively back into the gain medium at predominantly one of the multiple frequencies of laser radiation coinciding with the resonant modes of the external cavity, resulting in only one predominant lasing frequency and in the suppression of other frequencies of the laser radiation through self-injection locking.

3. The optical radiation source of claim 1 or 2, wherein the first and second free spectral ranges differ only slightly, the difference being typically within the order of magnitude of the largest width (FWHM) of the resonance modes of the internal and external cavities.

4. The optical radiation source of any one of claims 1-3, wherein the ratio of the first and second free spectral ranges is in the range of 0.9-1.1.

5. The optical radiation source of any one of claims 1-4, wherein the laser source is one of:
a Fabry-Perot laser diode,
a reflective semiconductor optical amplifier combined with a reflector to form an internal cavity having a plurality of resonance modes separated by the first free spectral range,
a semiconductor optical amplifier or a superluminescent diode combined with two reflectors to form an internal cavity having a plurality of resonance modes separated by the first free spectral range.

6. The optical radiation source of any one of claims 1-5, wherein the external cavity is tunable, allowing selective tuning of the resonance modes of the external cavity to control the lasing wavelength(s) of the laser source.

7. The optical radiation source of claim 6, wherein the external cavity is tunable by mechanically, electrically or thermally adjusting the physical properties, the refractive index, position, dimension or orientation of one or more elements of the external cavity.

8. The optical radiation source of any one of claims 1-7, further comprising an active or passive stabilization mechanism to maintain the alignment and/or the stability of the external cavity and/or laser source, and/or the coupling of the laser source to the external cavity.

9. The optical radiation source of any one of claims 1-8, wherein the external cavity is integrated into a photonic integrated circuit.

10. The optical radiation source of claim 9, wherein the laser source is optically coupled to or integrated into the photonic integrated circuit.

11. The optical radiation source of claim 9 or 10, wherein the external cavity comprises at least one frequency selective element, preferably microring resonators.

12. The optical radiation source of any one of claims 9-11, wherein the laser source is optically coupled to the external cavity via an integrated optical waveguide and an integrated adjustable phase shifter of the photonic integrated circuit.

13. The optical radiation source of any one of claims 9-12, wherein the external cavity contains a fixed or tunable splitter to split the laser radiation into a first portion that is reflected to the laser source, and a second portion coupled out from the optical radiation source.
